(19) United States
(12) Patent Application Publication
(10) Pub. No.: US 2022/0181462 A1
(43) Pub. Date: Jun. 9, 2022

(54) FIN TRANSISTORS WITH SEMICONDUCTOR SPACERS

(71) Applicant: SEMICONDUCTOR COMPONENTS INDUSTRIES, LLC, Phoenix, AZ (US)

(72) Inventors: Jeffrey Peter GAMBINO, Gresham, OR (US); Kevin Alexander STEWART, Gresham, OR (US); Peter MOENS, Erwetegem (BE); David T. PRICE, Gresham, OR (US); Derryl ALLMAN, Camas, WA (US)

(73) Assignee: SEMICONDUCTOR COMPONENTS INDUSTRIES, LLC, Phoenix, AZ (US)

(21) Appl. No.: 17/247,212

(22) Filed: Dec. 3, 2020

(51) Int. Cl. H01L 29/49; H01L 29/24; H01L 29/08; H01L 29/417; H01L 29/78; H01L 29/06; H01L 29/423; H01L 29/786; H01L 29/66

(52) U.S. Cl. CPC H01L 29/4983; H01L 29/247; H01L 29/0847; H01L 29/41791; H01L 29/785; H01L 29/0673; H01L 29/66969; H01L 29/42392; H01L 29/4908; H01L 29/78618; H01L 29/78693; H01L 29/78696; H01L 29/41733

(57) ABSTRACT

In a general aspect, a transistor can include a fin having a proximal end and a distal end. The fin can include a dielectric portion longitudinally extending between the proximal end and the distal end, and a semiconductor layer disposed on the dielectric portion. The semiconductor layer can longitudinally extend between the proximal end and the distal end. The transistor can further include a source region disposed at the proximal end of the fin, and a drain region disposed at the distal end of the fin. The transistor can also include a gate dielectric layer disposed on a channel region of the semiconductor layer. The channel region can be disposed between the gate dielectric layer and the dielectric portion. The channel region can be longitudinally disposed between the source region and the drain region. The transistor can further include a conductive gate electrode disposed on the gate dielectric layer.

### TECHNICAL FIELD

This description relates to field-effect transistor (FET) devices and, more specifically, to field-effect transistors that include a fin (e.g., FinFETs) having semiconductor spacers.

### BACKGROUND

In some applications, transistor devices (and other electronic devices) implemented on a semiconductor die can be formed in a stacked configuration. For instance, semiconductor processing operations, which can be referred to as front-end-of-line (FEOL) processing, can be performed to produce a first set of devices (e.g., transistors, a circuit, etc.) on a semiconductor die. After completion of such FEOL processing, additional semiconductor processing operations, which can be referred to as back-end-of-line (BEOL) processing, can be performed to produce a second set of devices that are stacked on (formed on, disposed on, etc.) the devices produced during the associated FEOL processing. For instance, devices produced during BEOL processing can be formed on (e.g., formed directly on, etc.) a planar layer, such as a dielectric layer, that is formed at the end of FEOL processing, and/or at the beginning of BEOL processing.

However, in current implementations, transistors (e.g., laterally-diffused transistors, planar transistors, etc.) formed during BEOL processing, referred to herein as BEOL transistors, can have certain drawbacks. For instance, current approaches for producing BEOL transistors can result in large semiconductor die sizes (e.g., to achieve a desired drive current for the BEOL transistors) and/or can have insufficient drive current per unit device area. Therefore, there is a need for BEOL transistors that have improved performance characteristics to reduce die sizes and/or increase drive current per unit device area.

### SUMMARY

In a general aspect, a transistor, such as a fin field-effect transistor (FinFET), can include a fin having a proximal end and a distal end. The fin can include a dielectric portion longitudinally extending between the proximal end and the distal end, and a semiconductor layer (e.g., semiconductor spacer) disposed on the dielectric portion. The semiconductor layer can longitudinally extend between the proximal end and the distal end. The transistor, e.g., the fin, can include a source region disposed at the proximal end of the fin, and a drain region disposed at the distal end of the fin (or vice versa). The transistor can further include a gate dielectric layer disposed on a channel region of the semiconductor layer. The channel region of the semiconductor layer can be disposed between the gate dielectric layer and the dielectric portion. The channel region of the semiconductor layer can be longitudinally disposed between the source region and the drain region. The transistor can further include a conductive gate electrode disposed on the gate dielectric layer. The gate dielectric layer can be disposed between the conductive gate electrode and the semiconductor layer.

In another general aspect, a transistor, such as a fin field-effect transistor (FinFET), can include a dielectric fin having a proximal end and a distal end, and a semiconductor layer disposed on the dielectric fin. The semiconductor layer can longitudinally extend between the proximal end of the dielectric fin and the distal end of the dielectric fin. The semiconductor layer can include a source region disposed at the proximal end of the dielectric fin, a drain region disposed at the distal end of the dielectric fin, and a channel region longitudinally disposed between the source region and the drain region. The transistor can also include a gate dielectric layer disposed on the channel region of the semiconductor layer. The channel region of the semiconductor layer can be disposed between the gate dielectric layer and the dielectric portion. The transistor can also include a conductive gate electrode disposed on the gate dielectric layer. The gate dielectric layer can be disposed between the conductive gate electrode and the semiconductor layer.

In another general aspect, a transistor, such as a fin field-effect transistor (FinFET), can include a fin having a proximal end and a distal end. The fin can include a source region disposed at the proximal end, a drain region disposed at the distal end; and a channel region disposed between the source region and the drain region. The transistor, e.g., the fin, can further include a first coaxial structure including a first dielectric core, a first semiconductor layer concentrically disposed on the first dielectric core, and, in the channel region, a first gate dielectric layer concentrically disposed on the first semiconductor layer. The first coaxial structure can longitudinally extend between the proximal end and the distal end. The transistor, e.g., the fin, can also include a second coaxial structure including a second dielectric core, a second semiconductor layer concentrically disposed on the second dielectric core, and, in the channel region, a second gate dielectric layer concentrically disposed on the second semiconductor layer. The second coaxial structure can longitudinally extend between the proximal end and the distal end. The transistor can also include a conductive gate electrode that, in the channel region, surrounds, at least in part, the first coaxial structure and the second coaxial structure.

### BRIEF DESCRIPTION OF THE DRAWINGS

FIG. 1 is a diagram that schematically illustrates a fin field-effect transistor (FinFET) with multiple segments that can be implemented using fins including semiconductor spacers.

FIG. 2 is a diagram illustrating a first cross-sectional view of an implementation of the FinFET of FIG. 1.

FIG. 3 is a diagram illustrating a second cross-sectional view of the implementation of the FinFET of FIG. 1 shown in FIG. 2.

FIG. 4 is a diagram illustrating a cross-sectional view of a gate of a FinFET of the FinFET of FIGS. 2 and 3.

FIG. 5 is a diagram illustrating a cross-sectional view of a source (or drain) region of the FinFET of FIGS. 2 and 3.

FIGS. 6A through 9B are cross-sectional diagrams illustrating a process for producing the FinFET of FIGS. 2 and 3.

FIG. 10 is a diagram illustrating a first cross-sectional view of another implementation of the FinFET of FIG. 1.

FIG. 11 is a diagram illustrating a cross-sectional view of a gate of the FinFET of FIG. 10.

FIG. 12 is a diagram illustrating a cross-sectional view of a source (or drain) region of the FinFET of FIG. 10.

FIG. 13 is a diagram illustrating a second cross-sectional view of the implementation of the FinFET of FIG. 10.

FIG. 14 is a diagram illustrating the second cross-sectional view of FIG. 13 with some elements illustrated as transparent to illustrate structure of the fin of the FinFET.

FIGS. 15A through 15G are isometric diagrams schematically illustrating a process for producing an implementation of the FinFET of FIGS. 10-14.

In the drawings, which are not necessarily drawn to scale, like reference symbols may indicate like and/or similar components (elements, structures, etc.) in different views. The drawings illustrate generally, by way of example, but not by way of limitation, various implementations discussed in the present disclosure. Reference symbols shown in one drawing may not be repeated for the same, and/or similar elements in related views. Reference symbols that are repeated in multiple drawings may not be specifically discussed with respect to each of those drawings, but are provided for context between related views. Also, not all like elements in the drawings are specifically referenced with a reference symbol when multiple instances of an element are illustrated in a given view.

### DETAILED DESCRIPTION

The present disclosure is directed to transistor devices (and associated methods of manufacture) that can be implemented as back-end-of-line (BEOL) transistors, and can overcome the drawbacks of current approaches noted above. For instance, the present disclosure is directed to transistors, e.g., field-effect transistors (FET), that are implemented using at least one semiconductor spacer. In the disclosed implementations, source, drain and channel regions of the transistor can be defined, at least in part, by the semiconductor spacer(s).

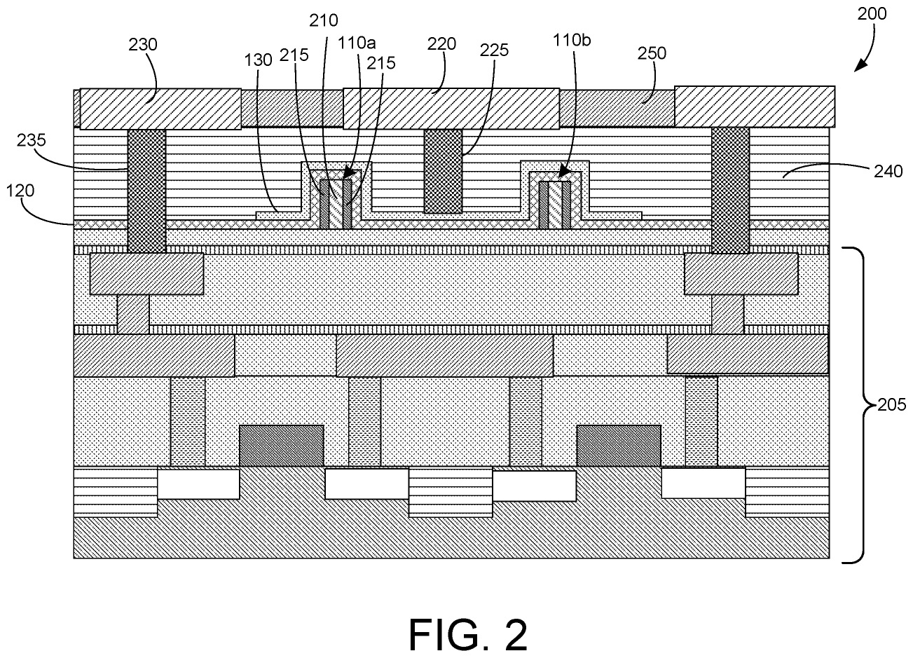

In the implementations described herein, semiconductor spacers can be formed on one or more dielectric portions of a fin. For instance, in some implementations, such as the example implementations shown in FIGS. 2-9B, a dielectric portion of a fin can be implemented as a vertical fin (e.g., such as a dielectric plate that is arranged orthogonally to an associated semiconductor die) and one or more semiconductor spacers can be formed on the vertical, dielectric fin.

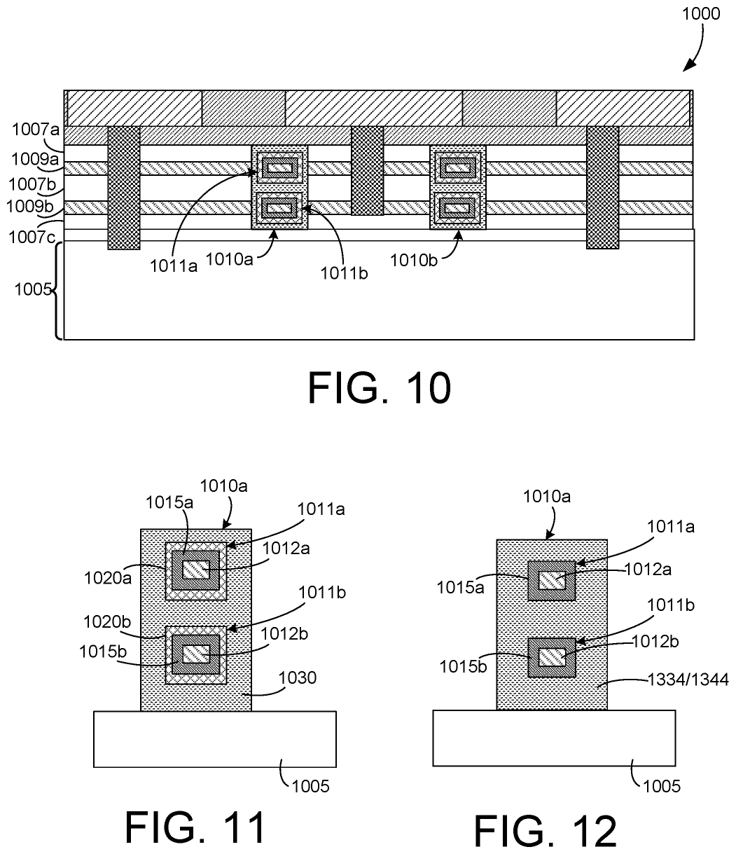

In other implementations, such as the example implementations shown in FIGS. 10-15G, a fin of a transistor can include one or more (two, three, etc.) coaxially arranged structures. For instance, such a coaxially arranged structure can include a semiconductor spacer that is coaxially arranged with (concentrically disposed on) a dielectric portion (e.g., a dielectric core), and a gate dielectric layer that is coaxially arranged with (concentrically disposed on) the dielectric portion and the semiconductor layer, such as shown in, at least, FIGS. 10-12. In some implementations, such coaxially arranged structures can implement wires, or sheets (e.g., nano-wires or nano-sheets) of an associated transistor.

For purposes of this disclosure, the example transistor implementations can be referred to as fin transistors, and/or fin field-effect transistors (FinFETs). The dielectric portion (or portions) of an associated fin of such FinFET devices can be referred to as a dummy fin, as the dielectric portions are not active parts of the associated FinFET device, but provide structural support for formation of associated semiconductor spacers.

As described herein, such FinFET devices can be produced using conformal deposition techniques to form, e.g., semiconductor spacers, or other features. For instance, in some implementations, conformal deposition, such as atomic-layer deposition (ALD), can be implemented to produce semiconductor spacers, gate electrodes, source and drain contacts, as was as other elements of an associated transistor (FinFET). In some implementations, other techniques can be used to form features of the example FinFETs, e.g., thermal oxidation, non-conformal deposition processes, photolithography and etch processes, etc. For purposes of brevity and clarity, the specific semiconductor process operations for forming a given feature of the example FinFETs may not be specifically described.

The example FinFET devices, which can be referred to as three-dimensional (3D) devices can provide improved performance over current (e.g., planar) devices. For instance, due to the 3D structure of the fins of the example implementations described herein, such FinFETs can provide increased current per unit device (e.g., layout) area, which can provide higher on current per unit device area, which can allow for reducing a size of an associated semiconductor die. Also, due, at least, to the structure the fins of the FinFETs described herein, such devices can have lower off current and/or can have steeper subthreshold slope (SS) than current planar devices.

In some implementations, the FinFET devices described herein can be implemented as BEOL transistors, e.g., in a stacked arrangement with front-end-of-line (FEOL) devices. In some implementations, the FinFET devices can be implemented independent of other electronic device, e.g., on semiconductor die that does not include stacked device structures, or as FEOL transistors. The example implementations described herein can be implemented using a number of appropriate semiconductor manufacturing process flows, such as sub-micron processes and/or deep sub-micron processes (e.g., 45 nanometer (nm) technologies, 65 nm technologies, etc.).

In some implementations, the example transistors described herein can be implemented (e.g., as BEOL, independent, and/or FEOL transistors) in CMOS image sensor, high-density memory devices, in conjunction with input/output (I/O) drivers operating at a higher voltage than an associated logic supply voltage, and/or in conjunction with switches for multi-chip heterogeneous integration, e.g., communication between a low-side voltage domain and a high-side voltage domain.

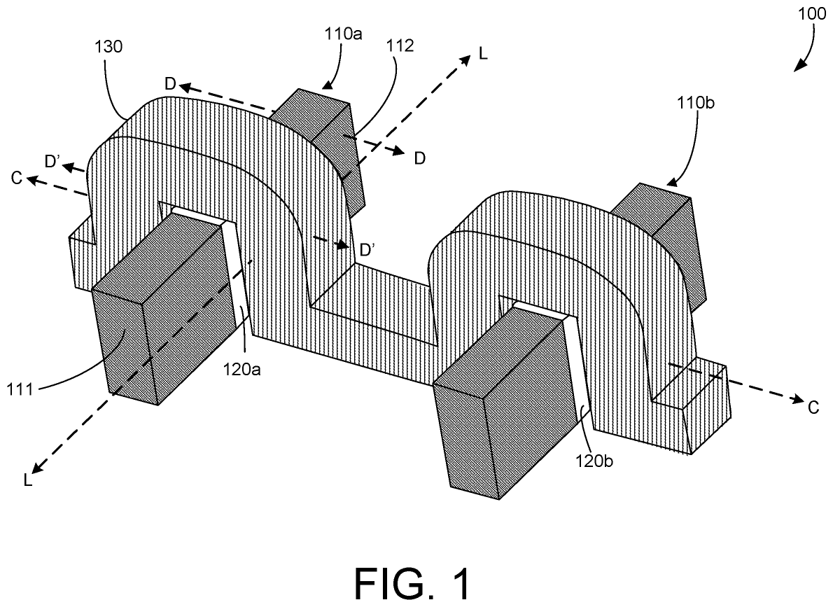

FIG. 1 is a diagram that schematically illustrates a FinFET 100 with multiple segments that can be implemented using fins including semiconductor spacers. For instance, the FinFET 100 includes a first segment that includes a fin 110a and a second segment that includes a fin 110b. For purposes of illustration in this example, the fin 110a and the fin 110b can have like structure, and are described as such. Accordingly, in following, any discussion of the fin 110a or the fin 110b, as well as associated elements of the FinFET 100, can apply equally to either fin.

As shown in FIG. 1, the fin 110a can have a proximal end 111 and a distal end 112. The indications of the proximal end 111 and the distal end 112 are relative, are indicated by way of example, and are for provided purposes of discussion. Depending on the arrangement of the FinFET 100 (or the other example FinFETs described herein), the proximal end 111 and the distal end 112 can be reversed, as can the source and drain regions discussed with respect to the various example implementations.

In some implementations, the fin 110a (and the fin 110b) can be implemented using the approaches described herein. For instance, the fin 110a can include at least one dielectric portion that longitudinally extends (e.g., along the line L-L) between the proximal end 111 and distal end 112. For instance, the at least one dielectric portion can include an oxide, e.g., silicon dioxide, or other dielectric material. As noted above, in some implementations, the dielectric portion of the fin 110a can be referred to as a dummy fin.

The fin 110a can also include at least one semiconductor layer (semiconductor spacer) that is/are respectively disposed on the at least one dielectric portion of the fin 110a. As with the dielectric portion of the fin 110a, the at least one semiconductor layer can longitudinally extend between the proximal end 111 and the distal end 112 of the fin 110a. In some implementations, the at least one semiconductor layer can include an amorphous oxide semiconductor. For instance, the amorphous oxide semiconductor can include at least one of indium gallium zinc oxide, zinc tantalum oxide, indium tin oxide, zinc tin oxide, and/or indium zinc oxide. In some implementations, the at least one semiconductor layer can include silicon, germanium, gallium arsenide, gallium nitride, silicon carbide, and so forth. In some implementations, the at least one semiconductor layer can include a direct bandgap semiconductor, or a zero bandgap semiconductor. Depending on the particular implementation, the at least one semiconductor layer of the fin 110a can be undoped (e.g., a semiconductor layer that is intrinsically n-type or p-type), or can be doped (e.g., in source and drain regions).

As discussed in further detail below with reference to the disclosed example implementations, the at least one semiconductor layer of the fin 110a can include (define, etc.) a source region that is disposed at (arranged at, located at, etc.) the proximal end 111 of the fin 110a, and a drain region that is disposed at (arranged at, located at, etc.) the distal end 112 of the fin 110a. In the example implementations described herein, the at least one semiconductor layer can also include (define, etc.) a channel region of the FinFET 100. The channel region of the fin 110a can be longitudinally disposed (longitudinally extend) between the source region and the drain region.

As illustrated in FIG. 1, the FinFET 100 can also include a gate dielectric layer 120a and a gate dielectric layer 120b (e.g., high-k gate dielectric layer) disposed on respective channel regions of the semiconductor layers of the fin 110a (e.g., a first segment of the FinFET 100) and the fin 110b (e.g., a second segment of the FinFET 100). For instance, in this implementation, the channel region of the fin 110a can be disposed between the gate dielectric layer 120a and a dielectric portion of the fin 110a. Further, in the FinFET 100, the channel region of the fin 110a is longitudinally disposed between the source region (e.g., located at the proximal end 111 of the fin 110a) and the drain region (e.g., located at the distal end 112 of the fin 110a).

As also shown in FIG. 1, the FinFET 100 includes a conductive gate electrode 130 that is disposed on the gate dielectric layer 120a and the gate dielectric layer 120b. For instance, for the fin 110a, the gate dielectric layer 120a (in the channel region of the fin 110a) is disposed between the conductive gate electrode 130 and the semiconductor layer of the fin 110a. In some implementations, the gate dielectric layer 120a and the gate dielectric layer 120b can include a dielectric material having a dielectric constant greater than or equal to approximately 3.9. For example, the gate dielectric layer 120a and the gate dielectric layer 120b can include one or more of silicon dioxide, silicon nitride, hafnium oxide, aluminum oxide, zirconium oxide, aluminum oxynitride, tantalum oxide, hafnium silicon oxide, lanthanum oxide, barium oxide, titanium oxide, strontium oxide, yttrium oxide, aluminum nitride, and/or calcium oxide.

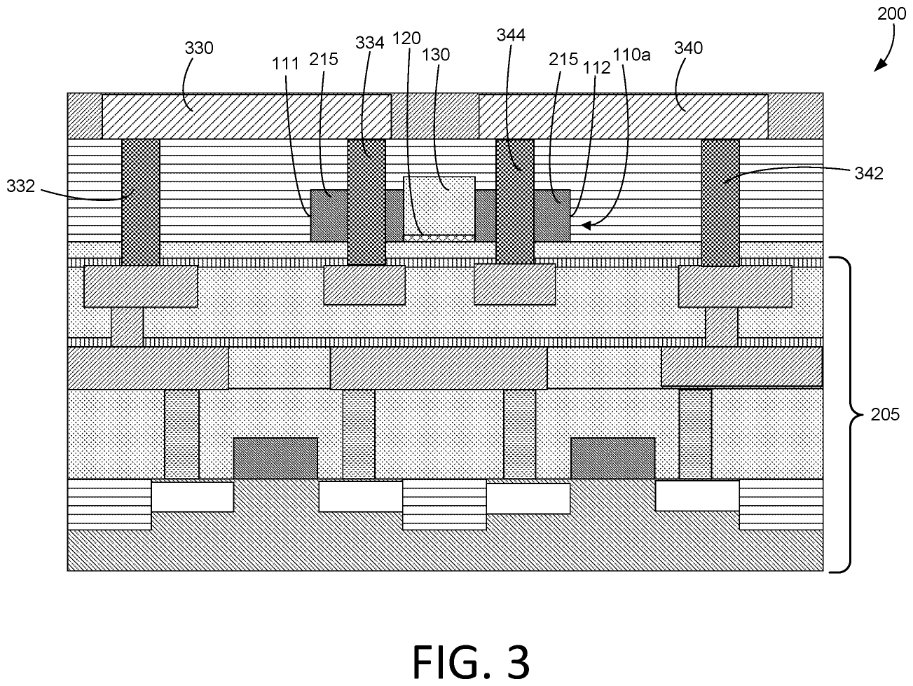

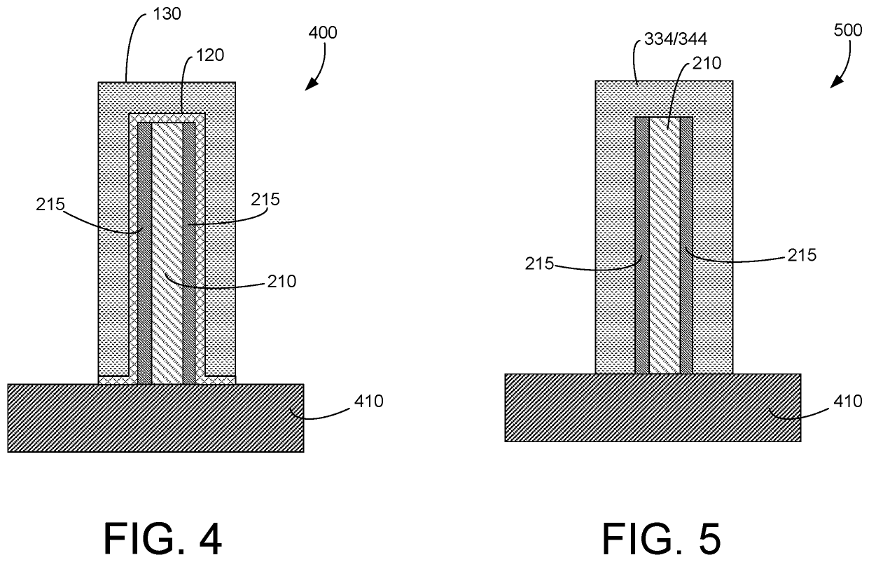

FIG. 1 includes lines C-C, D′-D′, D-D and L-L that correspond with (coincide with, are parallel with, etc.) section lines of the sectional views of the example implementations described herein. For instance, the line C-C corresponds with the sectional views of FIGS. 2 and 6A, 7A, 8A, 9A and 10, line D′-D′ corresponds with the sectional views of FIGS. 4 and 11, line D-D corresponds with the sectional views of FIGS. 5 and 12, and the line L-L corresponds with the sectional views of FIGS. 3, 6B, 7B, 8B and 9B. The lines C-C, D′-D′, D-D and L-L are provided for reference, and to illustrate the direction of the various sectional views of the corresponding figures. For purposes of illustration, in the various cross-sections below, certain elements of the illustrated devices may not be shown, so as not to obscure other elements of the illustrated views as described below.

FIG. 2 is a diagram illustrating a first cross-sectional view of a semiconductor device 200 including an implementation of the FinFET 100 of FIG. 1. As noted above, the cross-sectional view of FIG. 2 is along a section line that corresponds with the line C-C in FIG. 1. In this example, the cross-sectional view of FIG. 2 is through respective channel regions of the fin 110a and the fin 110b. FIG. 3 is a diagram illustrating a second cross-sectional view of the device 200 including the implementation of the FinFET 100 of FIG. 1 shown in FIG. 2. As noted above, the cross-sectional view of FIG. 3 is along a section line that corresponds with the line L-L in FIG. 1. In this example, the cross-sectional view of FIG. 3 is through the gate conductor 130 on the right side of the fin 110a in FIG. 1 (and FIG. 2). For purposes of discussion and illustration, the views of the device 200 in FIGS. 2 and 3 will described in conjunction with one another.

As shown in FIGS. 2 and 3, the device 200 can include a FEOL portion 205, which can include transistors and/or other electronic devices produced during a FEOL processing flow. The particular devices and arrangement of the FEOL portion 205 will depend on the particular implementations and, in this example, the FEOL portion 205 is shown by way of example and for purposes of illustration. Accordingly, specific details regarding the FEOL portion 205 are not discussed herein.

As shown in FIG. 2, the device 200 includes a fin 110a and a fin 110b (such as the fins of the FinFET 100 shown in FIG. 1). As with FIG. 1, in FIG. 2 (as well as related views) the fin 110a and the fin 110b can have like structure, and are described as such. Accordingly, in the following, any discussion of the fin 110a or the fin 110b, as well as associated elements, can apply equally to either fin. In this example, and as shown in FIG. 2, the fin 110a can include a dielectric portion 210 (e.g., a vertical oxide fin).

The fin 110a of this example can also include a semiconductor layer 215 (semiconductor spacer) that is disposed on the fin 110a. In this example, as can be seen from FIGS. 2 and 3 in combination, the semiconductor layer 215 can have a first portion disposed on a first longitudinal face of the dielectric portion 110a (e.g., a left side of the fin 110a in FIG. 2), and a second portion disposed on a second longitudinal face of the fin 110a (e.g., a left side of the fin 110a in FIG. 2). As illustrated in FIG. 2, the second longitudinal face can be opposite the first longitudinal face. As shown in FIG. 3, the semiconductor layer 215 can have a third portion disposed on the proximal face of the fin 110a (e.g., at the proximal end 111), and a fourth portion disposed on a distal face of the fin 110a (e.g., at the distal end). Further as can be seen in FIG. 2 (as well as in FIG. 4), an upper face of the fin 110a can exclude the semiconductor layer 215, which can be a result of, e.g., a spacer etch process. Such an arrangement can prevent non-uniform fields from forming (e.g., at the top corners of the fin) during operation of the FinFET, which can prevent and/or reduce a leakage current of the FinFET. In some implementations, the semiconductor layer 215 can include (e.g., can be formed using) multiple semiconductor layers.

As shown in FIGS. 2 and 3, the FinFET of the device 200 also includes a gate dielectric layer 120 and a conductive gate electrode 130. In this example, the gate dielectric layer 120 can correspond with the gate dielectric layer 120a and the gate dielectric layer 120b in FIG. 1 (e.g., can be a high-k dielectric layer), while the gate electrode 130 in FIGS. 2 and 3 can correspond with the conductive gate electrode 130 of FIG. 1. In some implementations, the conductive gate electrode 130 can include metal, doped polysilicon, or other appropriate low resistance material. As shown in FIGS. 2 and 3, the gate dielectric layer 120 and the conductive gate electrode 130 can be disposed on the fin 110a in a channel region of the associated FinFET (e.g., a channel region of the semiconductor layer 215). FIGS. 2 and 3 illustrate an example arrangement of the gate dielectric layer 120 and the conductive gate electrode 130. In some implementations, other arrangements are possible. For instance, in some implementations, the gate dielectric layer 120 may not extend beyond the conductive gate electrode 130 (e.g., may be removed to the left of the conductive gate electrode 130 and to the right of the conductive gate electrode 130 in FIG. 2. In some implementations, still other arrangements of the gate dielectric layer 120 and the conductive gate electrode 130 are possible.

As also shown in FIGS. 2 and 3, electrical connections can be formed to circuitry in the FEOL portion 205, to the FinFET, and/or between the FinFET and circuitry of the FEOL portion 205. For instance, as in FIG. 2, a metal layer 220 and a metal layer 230 can be used to implement such electrical contacts. For instance, a contact 225 (e.g., a tungsten plug, etc.) can be formed between the metal layer 220 and the gate electrode 130 of the FinFET of the device 200. As also shown in FIG. 2, a contact 225, a contact 235 (e.g., a tungsten plug, etc.) can be formed between metal layer 230 and circuitry of the FEOL portion 205. As shown in FIG. 2, the device 200 can include a dielectric layer 240 and a dielectric layer 250, which can electrically isolate the metal layers and contacts from other elements of the device 200 (e.g., from elements to which an electrical connection is not intended).

As shown in FIG. 3, the device 200 can include a metal layer 330, a contact 332 and a contact 334 that can, collectively, implement an electrical connection between a source region of the associated FinFET (e.g., located at the distal end 111 of the fin 110a) and circuitry of the FEOL portion 205. That is, the contact 334 can be electrically coupled with a source region of the fin 110a. Similarly, the device 200 can include a metal layer 340, a contact 342 and a contact 344 that can, collectively, implement an electrical connection between a drain region of the associated FinFET (e.g., located at the distal end 112 of the fin 110a) and circuitry of the FEOL portion 205. That is, the contact 344 can be electrically coupled with a drain region of the fin 110a.

FIG. 4 is a diagram illustrating a cross-sectional view of a gate structure 400 of the FinFET of FIGS. 2 and 3 (e.g., an implementation of the FinFET 100 of FIG. 1). As noted above, the cross-sectional view of FIG. 4 is along a section line that corresponds with the line D′-D′ in FIG. 1. In this example, the cross-sectional view of FIG. 4 is through a channel region (e.g., through the gate structure 400) of the fin 110a. As shown in FIG. 4, the gate structure 400 is illustrated as being disposed on a planar layer 410, which, in some implementations, can be a planar layer of a FEOL portion of a corresponding semiconductor device (e.g., the FEOL portion 205 of FIG. 2). In some implementations, the planar layer 410 can be of a same material as a dielectric fin 210 of the gate structure 400. For example, a dielectric layer (e.g., a thermal silicon dioxide layer, a deposited dielectric layer, etc.) can be formed, and the planar layer 410 and the dielectric fin 210 can then be formed from that dielectric layer (e.g., using photolithography, etching, polishing, etc.).

As further shown in FIG. 4, the gate structure 400 includes the semiconductor layer 215, which can be formed using a conformal deposition process, such as ALD. Depending on the particular implementation, the semiconductor layer 215 of the gate structure 400 can include one or more of the materials noted above. The gate structure 400 can further include the gate dielectric layer 120 (e.g., a high-k gate dielectric layer) and the conductive gate electrode 130 (e.g., a metal electrode, a doped polysilicon electrode, etc.).

FIG. 5 is a diagram illustrating a cross-sectional view of a contact structure 500, which can implement a source region contact or a drain region contact of the FinFET of FIGS. 2 and 3 (e.g., an implementation of the FinFET 100 of FIG. 1). As noted above, the cross-sectional view of FIG. 5 is along a section line that corresponds with the line D-D in FIG. 1. In this example, the cross-sectional view of FIG. 5 can be through either a source region of the fin 110a (e.g., at a proximal end 111), or a drain region of the fin 110a (e.g., at a distal end 112). As shown in FIG. 5, as with the gate structure 400 of FIG., the contact structure 500 is illustrated as being disposed on the planar layer 410. As discussed with respect to FIG. 4, in some implementations, the planar layer 410 can be of a same material as the dielectric fin 210, which is also included in the contact structure 500 (e.g., a dielectric portion of an associated fin). Said another way, the dielectric fin 210 and the planar layer 410 can be formed from a same dielectric layer.

As further shown in FIG. 5, the contact structure 500 includes the semiconductor layer 215 (e.g., either a source region of the semiconductor layer 215, or a drain region of the semiconductor layer 215). In this example, the contact structure 500 can further include the contact 334 (e.g., a source contact) or the contact, 344 (e.g., a drain contact), such as shown and described with respect to FIG. 3.

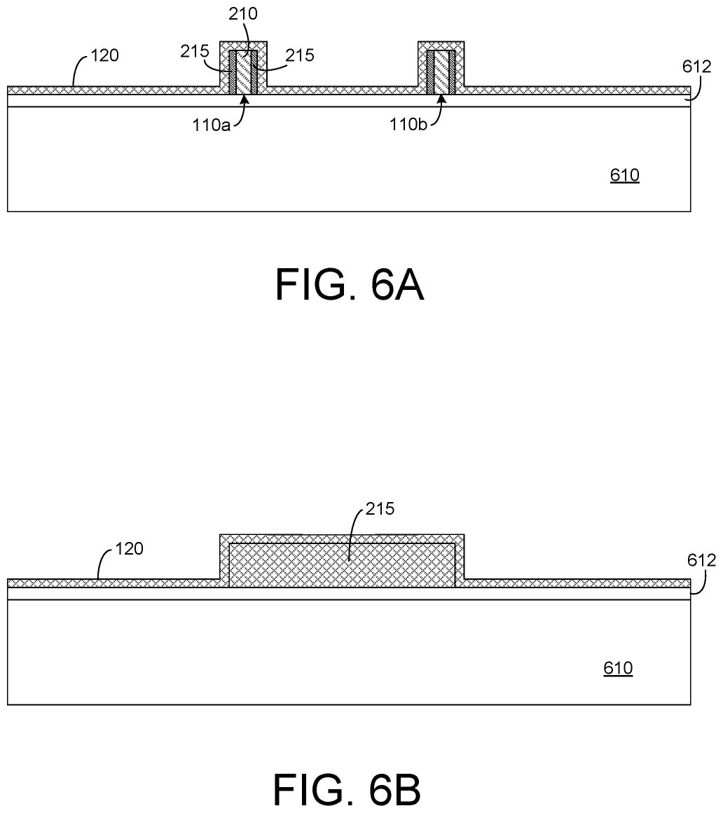

FIGS. 6A through 9B are cross-sectional diagrams illustrating a method for producing the FinFET of FIGS. 2 and 3. For instance, FIGS. 6A and 6B illustrate the FinFET after a first set of semiconductor process operations is performed, 7A and 7B illustrate the FinFET after a second set of semiconductor process operations is performed, 8A and 8B illustrate the FinFET after a third set of semiconductor process operations is performed, and 9A and 9B illustrate the FinFET after a fourth set of semiconductor process operations is performed.

In this example, FIGS. 6A, 7A, 8A and 9A are cross-sectional views corresponding with the cross-sectional view of FIG. 2 (e.g., along the line C-C in FIG. 1). Also in this example, FIGS. 6B, 7B, 8B and 9B are cross-sectional views corresponding with the cross-sectional view of FIG. 3 (e.g., along the line L-L in FIG. 1). Further in this example, the FinFET is shown as being formed on a substrate 610 and a planar layer 612, where, in some implementations, the substrate 610 can include circuitry formed in FEOL processing, such as described herein. In some implementations, the substrate 610 can exclude FEOL circuitry, and the FinFET can be formed without being stacked with, or on other circuitry. For the sake of brevity and clarity, specific details of the substrate 610 and the planar layer 612, which will depend on the particular implementation, are not described here.

Referring to FIGS. 6A and 6B, after the first set of semiconductor processing operations is performed, the fin 110a and the fin 110b are formed on the planar layer 612. For instance, with reference to the fin 110a in FIG. 6A, after performing the first set of operations, the dielectric fin 210 (dummy fin) is defined. In some implementations, such as in examples described herein, the dielectric fin 210 can be formed from a same material (e.g., a common dielectric material layer) as the planar layer 612. Also with reference to the fin 110a in FIG. 6A, after performing the first set of operations, the semiconductor layer 215 (semiconductor spacer) is defined (e.g., by conformal deposition, such as ALD). Further, as shown in FIGS. 6A and 6B, after performing the first set of operations, the gate dielectric layer 120 is also defined and can be disposed, at least, on the fin 110a (and the fin 110b), such as shown in FIG. 6B. For purposes of illustration and reference, an outline of the semiconductor layer 215 (e.g., within the gate dielectric layer 120) is shown in FIB. 6B, though the semiconductor layer 215 would not be visible in the cross-sectional view of FIG. 6B.

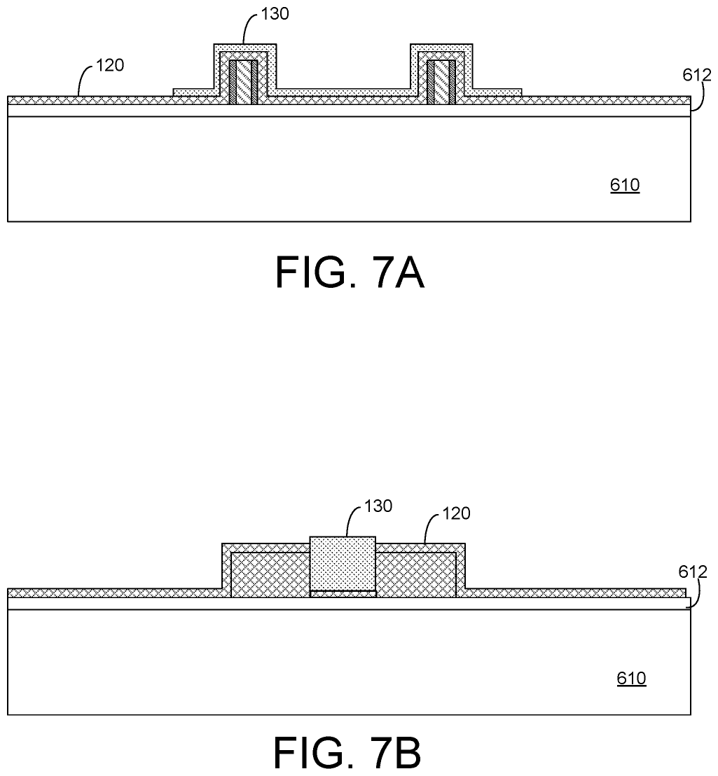

Referring to FIGS. 7A and 7B, after the second set of semiconductor processing operations is performed, the conductive gate electrode 130 is formed on the gate dielectric layer 120. For instance, as illustrated in FIGS. 7A and 7B, after performing the second set of operations, the conductive gate electrode 130 is defined. As with FIG. 6B, the outline of the semiconductor layer 215 (e.g., within the gate dielectric layer 120) is shown in FIB. 7B, though the semiconductor layer 215 would not be visible in the view of FIG. 7B. In some implementations, the gate electrode 130 can be formed using a deposition process, photolithography processes, and/or etching processes. In some implementations, forming the gate dielectric layer 130 can include doping the conductive gate electrode 130 (e.g., a polysilicon gate electrode).

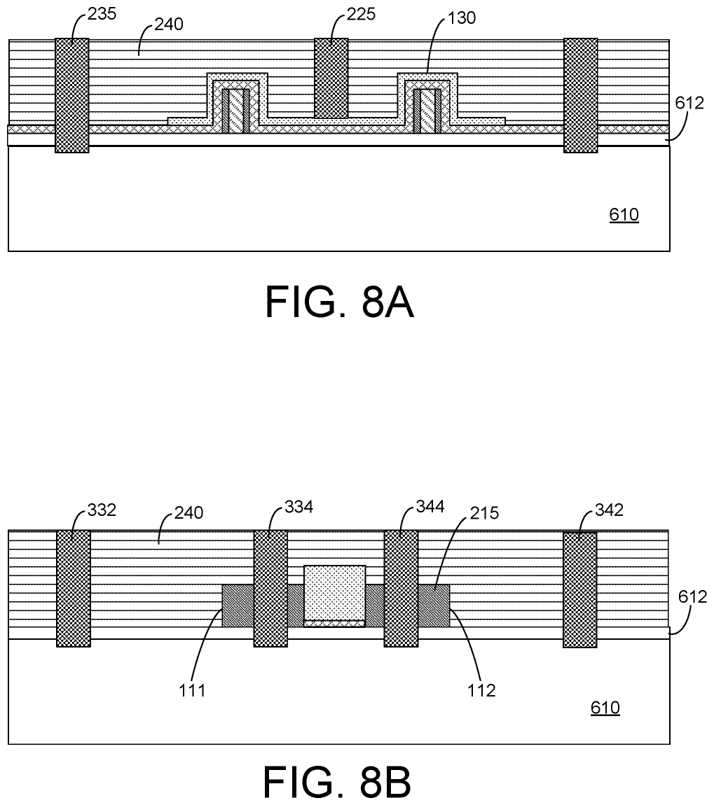

Referring to FIGS. 8A and 8B, after the third set of semiconductor processing operations is performed, the gate dielectric layer 120 is removed from the source and drain regions of the semiconductor layer 215, the dielectric layer 240 is deposited, and the contacts (e.g., contacts 225, 235, 332, 334, 342 and 344) are defined. For instance, as illustrated in FIG. 8B (as compared with FIG. 7B), after performing the third set of operations, the gate dielectric layer 120 is removed from the proximal end 111 (e.g., source region) and the distal end 112 (e.g., drain region) of the semiconductor layer 215. Further, as shown in FIG. 8A, after performing the third set of operations, the contact 225 to the conductive gate electrode 130 is defined, as are other contacts, such as the contact 235, which can be an electrical connection to FEOL circuitry in this example. Also, as shown in FIG. 8B, after performing the third set of operations, the contact 334 to the source region of the semiconductor layer 215 and the contact 344 to the drain region of the semiconductor layer 215 are defined, as are other contacts, such as 332 and 342 (e.g., electrical connections to FEOL circuitry).

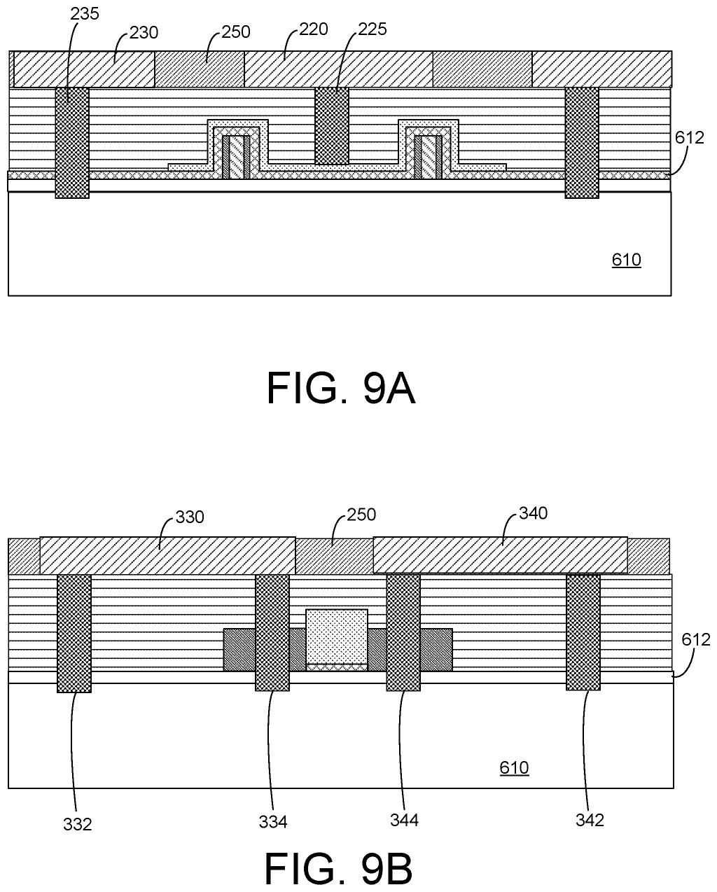

Referring to FIGS. 9A and 9B, after the fourth set of semiconductor processing operations is performed, the dielectric layer 250 is deposited, and metal interconnect layers (e.g., layers 220, 230, 330 and 340) are defined. That is, the fourth set of operations (e.g., which can include deposition, photolithography and/or etching operations) can define the interlayer dielectric (the dielectric layer 250) and metal interconnects (e.g., for the FinFET, and between the FinFET and other circuitry, such as FEOL circuitry).

FIG. 10 is a diagram illustrating a first cross-sectional view of a semiconductor device 1000 including another implementation of the FinFET 100 of FIG. 1. As shown in FIG. 10, the FinFET of the device 1000 includes a fin 1010a and a fin 1010b. As noted above, the cross-sectional view of FIG. 10 is along a section line that corresponds with the line C-C in FIG. 1. In this example, the cross-sectional view of FIG. 10 is through respective channel regions of the fin 1110a and the fin 1110b. As with the fin 110a and the fin 110b of the FinFETs shown in FIGS. 2 and 3, the fin 1110a and the fin 1110b can have like structure, and are described as such. Accordingly, in the following, any discussion of the fin 1110a or the fin 1110b, as well as associated elements, can apply equally to either fin.

As with the device 200 shown, at least, in FIGS. 2 and 3, the device 1000 can include a substrate 1005 (e.g., with or without FEOL circuitry), contacts, metal interconnects, dielectric layers (e.g., inter-layer dielectrics) and so forth. In some implementations, the substrate 1005 can include an associated planar layer, such as those described. For purposes of brevity, the specific arrangement of such elements of the device 1000 are not described in detail with respect to the device 1000, and their arrangement will depend on the particular implementation.

As shown in FIG. 10, the fin 1010a (as well as the fin 1010b) can include a first coaxial structure 1011a and a second coaxial structure 1011b, which can be nano-wire structures and/or nano-sheet structures. Example details of the first coaxial structure 1011a and the second coaxial structure 1011b are described further below with respect to FIGS. 11 and 12. In some implementations, the fin 1010a can include a different (e.g., fewer or greater) number of coaxial structures than illustrated in FIG. 10.

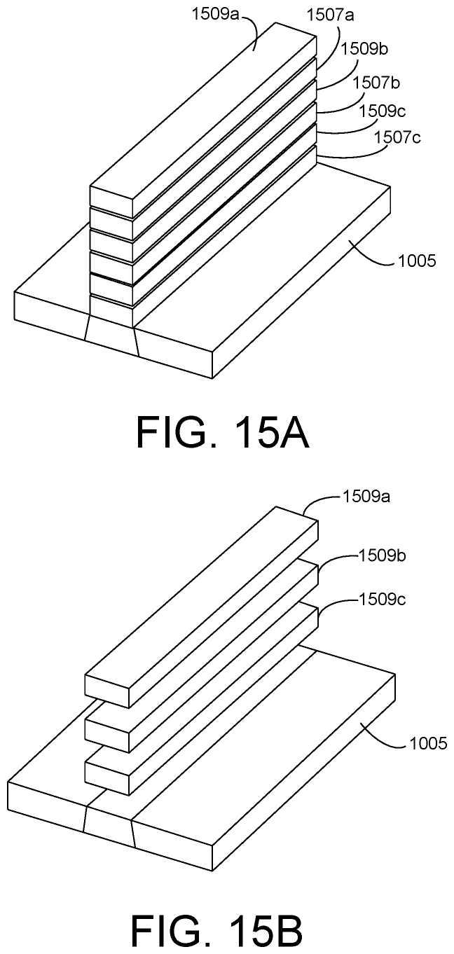

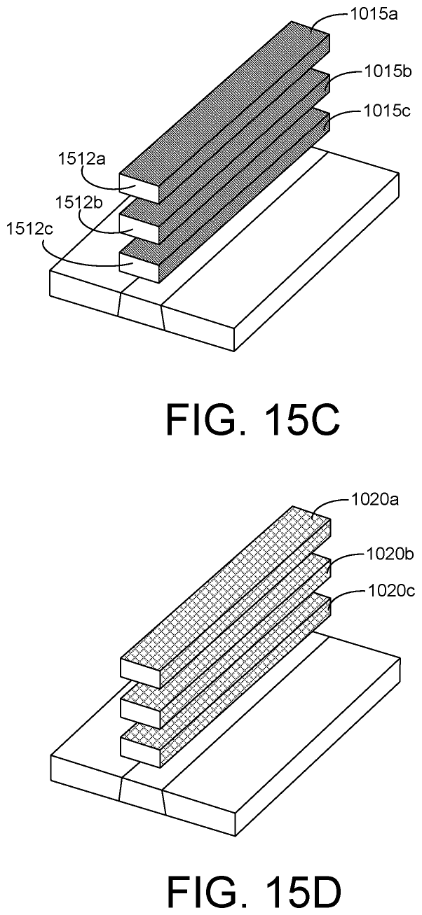

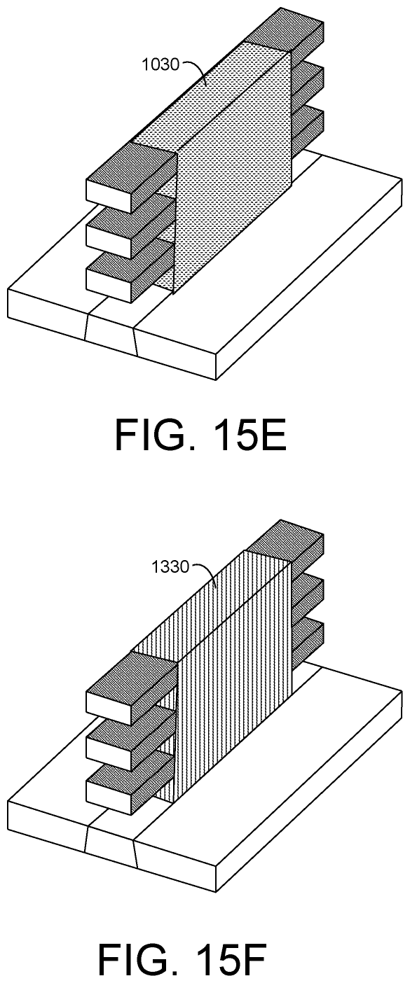

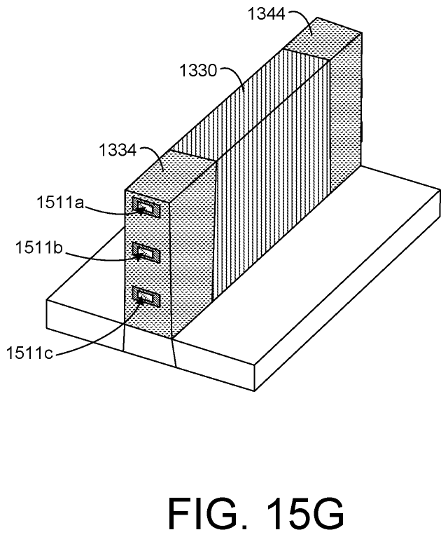

As also shown in FIG. 10, the FinFET of the device 1000 (e.g., the first coaxial structure 1011a and the second coaxial structure 1011b) can be implemented using an arrangement of alternate material layers. For instance, in the example of FIG. 10, the device 1000 includes material layers 1007a, 1007b and 1007c, which are alternately arranged with material layers 1009a and 1009b, such as shown in FIG. 10. In some implementations, the material layers 1007a, 1007b and 1007c can includes a first material, while the material layers 1009a and 1009b can include a second material. In this example, the material of the material layers 1007a, 1007b and 1007c in the fin 1010a can be removed (selectively etched), such that cantilevers of the material of the material layers 1009a and 1009b are formed in the fin 1010a. For instance, in some implementations, the material layers 1007a, 1007b and 1007c can include a glass material (e.g., such as a phosphosilicate glass (PSG), and the material layers 1009a and 1009b can include an oxide material (e.g., silicon dioxide). Formation of such cantilevers is shown in further detail with respect the manufacturing method of FIGS. 15A-15G.

FIG. 11 is a diagram illustrating a cross-sectional view of the fin 1010a of FIG. 10. As noted above, the cross-sectional view of FIG. 11 is along a section line that corresponds with the line in FIG. 1. In this example, the cross-sectional view of FIG. 11 is through a channel region of the fin 1010a (including the first coaxial structure 1011a and the second coaxial structure 1011b).

As shown in FIG. 11, in the channel region of the FinFET of FIG. 10, the first coaxial structure 1011a and the second coaxial structure 1011b include respective dielectric cores 1012a and 1012b. In this example, the coaxial structures 1011a and 1011b, in the channel region of the associated FinFET, further include respective semiconductor layers (semiconductor spacers) 1015a and 1015b, which can be formed (concentrically formed on the dielectric cores) using a conformal deposition process, such as ALD. As also shown in FIG. 11, the first coaxial structure 1011a and the second coaxial structure 1011b further include respective gate dielectric (e.g., high-k dielectric) layers 1020a and 1020b that are respectively disposed (concentrically disposed) on the semiconductor layers 1015a and 1015b. Depending on the particular implementation, the semiconductor layers 1015a and 1015b can include one or more of the materials noted above. In this example, the fin 1010a can further include, in the channel region of the associated FinFET, a conductive gate electrode 1030 (e.g., a metal gate electrode, a doped polysilicon gate electrode, etc.). As shown in FIG. 11, the conductive gate electrode 1030 can, at least in part, surround the first coaxial structure 1011a and the second coaxial structure 1011b to define respective gates (and channel regions) for each of the first coaxial structure 1011a and the second coaxial structure 1011b.

FIG. 12 is a diagram illustrating a cross-sectional view of a contact structure, which can implement a source region contact or a drain region contact of the FinFET of FIG. 10. As noted above, the cross-sectional view of FIG. 10 is along a section line that corresponds with the line D-D in FIG. 1. In this example, the cross-sectional view of FIG. 12 can be through either a source region of the fin 1010a (e.g., at a proximal end 111, such as shown in FIG. 1), or a drain region of the fin 1010a (e.g., at a distal end 112, such as shown in FIG. 1).

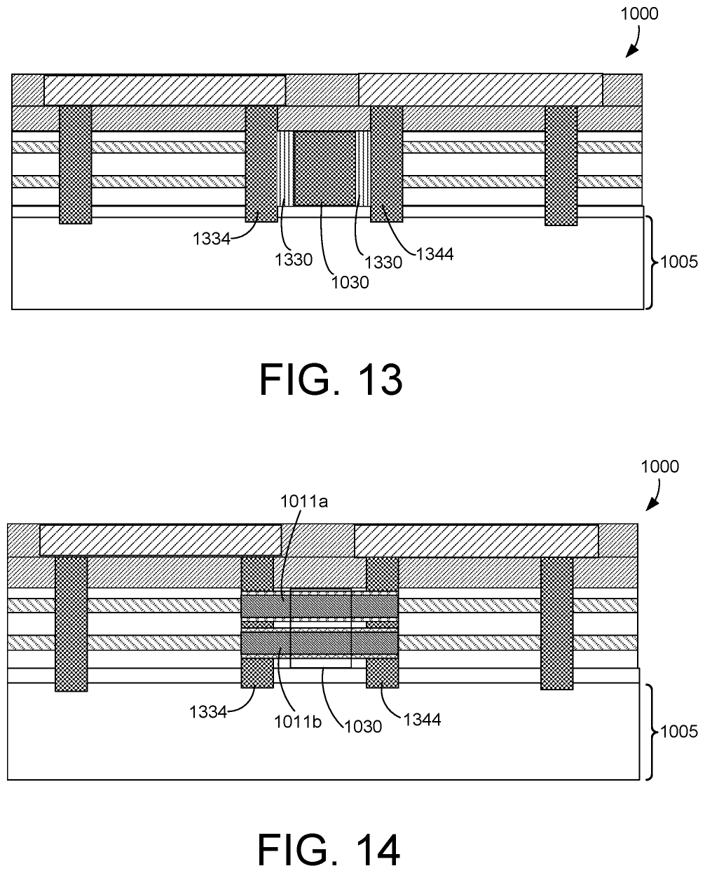

As shown in FIG. 12 (as compared with FIG. 11), the respective dielectric layers 1012a and 102b can be removed from the fin 1010a and the fin 1010b in the source and drain regions. The contact structure can include contact material (e.g., a tungsten plug, etc.) 1334 (in a source region) or 1344 in a drain region (such as further illustrated in in FIG. 13). The contact material 1334 or 1344 can define an electrical connection (e.g., an ohmic contact) with the semiconductor layers 1015a and 1015b (e.g., for respective source or drain connections to the first coaxial structure 1011a and the second coaxial structure 1011b).

FIG. 13 is a diagram illustrating a second cross-sectional view of the device 1000 of FIG. 10. As noted above, the cross-sectional view of FIG. 13 is along a section line that corresponds with the line L-L in FIG. 1. In this example, the cross-sectional view of FIG. 13 is through the conductive gate electrode (gate conductor) 1330 (e.g., in and out of the page) on the right side of the fin 1010a in FIG. 11. FIG. 13 illustrates the arrangement of the (source) contact 1334 and the (drain) contact 1344 of the FinFET, with respect to its conductive gate electrode 1030 of FIGS. 10-12. As shown in FIG. 13, the FinFET in this example also include a spacer 1330 that can electrically isolate the contacts 1334 and 1344 from the conductive gate electrode 1030. In some implementations, the spacer 1330 can be a nitride (e.g., silicon nitride) spacer, and can be disposed over the conductive gate electrode 1030, such as shown in FIG. 15F.

FIG. 14 is a diagram illustrating the second cross-sectional view of FIG. 13 with some elements illustrated as transparent to illustrate structure of the fin 1010a of the FinFET of the device 1000 in FIG. 10. For instance, the conductive gate electrode 1030, the spacer 1330, and portions of the contacts 1334 and 1344 are illustrate as being transparent in FIG. 14, such that arrangement of the first coaxial structure 1011a and the second coaxial structure 1011b with the conductive gate electrode 1030, the spacer 1330, and the contacts 1334 and 1344 can be seen. For purpose of reference, an outline of the conductive gate electrode 1030 is shown in FIG. 14.

FIGS. 15A through 15G are isometric diagrams schematically illustrating a process for producing an implementation of the FinFET of FIGS. 10-14. As compared to the FinFET of FIGS. 10-14, the example implementation of FIGS. 15A-15G includes three coaxial structures, rather than two as shown in the device 1000. Also, for purposes of illustration, only portions of the alternating material layers used to produce a fin of the FinFET are shown in FIGS. 15A-15G, such that those material layer portions appear to be floating. It will be appreciated that, in such implementations (such as the FinFET of FIG. 10), such material layer portions can be supported on each end (proximal and distal end), such as shown in FIG. 14, where the conductive gate electrode 1030, the spacer 1330, and portions of the contacts 1334 and 1344 are shown as being transparent to illustrate the arrangement of the coaxial structures 1011a and 1011b.

Referring to FIG. 15A, alternating material layers 1507a, 1507b, 1507c, 1509a, 1509b, and 1509c can be formed on the substrate 1005 (such as the substrate 1005 of FIG. 10, for example). As discussed above with respect to FIG. 10, the alternating material layers in FIG. 15A can be formed (e.g., deposited, grown, etc.) from different materials. For instance, in some implementations, the material layers 1509a, 1509b, and 1509c can include a dielectric material, such as silicon dioxide, and the material layers 1507a, 1507b, and 1507c can include a glass material, such as PSG. In some implementations, other materials can be used.

Referring to FIG. 15B, a selective etch (e.g., in combination with photolithography operations) can be performed on the structure of FIG. 15A to remove the material layers 1507a, 1507b and 1507c, leaving cantilevers of material from layers 1509a, 1509b and 1509c, which can then be used to implement dielectrics cores 1512a, 1512b and 1512c for coaxial structures of an associated FinFET, such as shown in FIG. 15C. As further shown in FIG. 15C, a conformal deposition process (e.g., ALD) can be performed to form (e.g., concentrically dispose, deposit, etc.) respective semiconductor layers (spacers) 1015a, 1015b and 1015c on the dielectric cores 1512a, 1512b and 1512c. The semiconductor layers (spacers) 1015a, 1015b and 1015c can be formed from one or more semiconductor materials, such as those described herein.

As shown in FIG. 15D, gate dielectric layers 1020a, 1020b and 1020c can be respectively formed (e.g., deposited, grown, etc.) on the semiconductor layers (spacers) 1015a, 1015b and 1015c. Continuing to FIG. 15E, the conductive gate electrode 1030 can be formed and gate dielectric material (from gate dielectric layers 1020a, 1020b and 1020c) in source (e.g., left front, or proximal end) and drain areas (e.g., right back, or distal end) of the coaxial structures can be removed. As shown in FIG. 15F, the spacer 1330 (e.g., a silicon nitride spacer) can then be formed over the conductive gate electrode conductive gate electrode 1030. Continuing to FIG. 15G, the source contact 1334 and the drain contact 1344 can be formed. As illustrated in FIG. 15G, the coaxial 1511a, 1511b and 1511c can be disposed within the contacts 1334 and 1344, as well as within the conductive gate electrode 1030 and the spacer 1330.

It will be understood, for purposes of this disclosure, that when an element, such as a layer, a region, or a substrate, is referred to as being on, disposed on, connected to, electrically connected to, coupled to, or electrically coupled to another element, it may be directly on, connected or coupled to the other element, or one or more intervening elements may be present. In contrast, when an element is referred to as being directly on, directly disposed on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to, vertically adjacent to, or horizontally adjacent to.

Some implementations may be implemented using various semiconductor processing and/or packaging techniques. Some implementations may be implemented using various types of semiconductor processing techniques associated with semiconductor substrates including, but not limited to, for example, silicon (Si), gallium arsenide (GaAs), gallium nitride (GaN), silicon carbide (SiC), direct bandgap semiconductors, amorphous oxide semiconductors, and/or so forth.

While certain features of various example implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A fin field-effect transistor (FinFET) comprising:
a fin having a proximal end and a distal end, the fin including:
a dielectric portion longitudinally extending between the proximal end and the distal end;
a semiconductor layer disposed on the dielectric portion, the semiconductor layer longitudinally extending between the proximal end and the distal end;
a source region disposed at the proximal end of the fin; and
a drain region disposed at the distal end of the fin;
a gate dielectric layer disposed on a channel region of the semiconductor layer, the channel region of the semiconductor layer being disposed between the gate dielectric layer and the dielectric portion, the channel region of the semiconductor layer being longitudinally disposed between the source region and the drain region; and
a conductive gate electrode disposed on the gate dielectric layer, the gate dielectric layer being disposed between the conductive gate electrode and the semiconductor layer.

2. The FinFET of claim 1, wherein the dielectric portion is an oxide fin.

3. The FinFET of claim 1, wherein the dielectric portion is coaxially arranged with the semiconductor layer and the gate dielectric layer, the conductive gate electrode surrounding, at least in part, the coaxially arranged dielectric portion, semiconductor layer and gate dielectric layer.

4. The FinFET of claim 3, wherein the dielectric portion is a first dielectric portion, the semiconductor layer is a first semiconductor layer, and the gate dielectric layer is a first gate dielectric layer,
the fin of the FinFET further including:
a second dielectric portion longitudinally extending between the proximal end and the distal end; and
a second semiconductor layer disposed on the second dielectric portion, the second semiconductor layer longitudinally extending between the proximal end and the distal end,
the FinFET further comprising:
a second gate dielectric layer disposed on a channel region of the second semiconductor layer, the channel region of the second semiconductor layer being disposed between the second gate dielectric layer and the second dielectric portion, the channel region of the second semiconductor layer being longitudinally disposed between the source region and the drain region, the second dielectric portion being coaxially arranged with the second semiconductor layer and the second gate dielectric layer, the conductive gate electrode surrounding, at least in part, the coaxially arranged second dielectric portion, second semiconductor layer and second gate dielectric layer.

5. The FinFET of claim 4, further comprising:
a source contact that, in the source region, surrounds, at least in part:
the coaxially arranged first dielectric portion and first semiconductor layer; and
the coaxially arranged second dielectric portion and second semiconductor layer,
the source contact, in the source region, being disposed on, and electrically coupled with the first semiconductor layer and the second semiconductor layer; and
a drain contact that, in the drain region, surrounds, at least in part:
the coaxially arranged first dielectric portion and first semiconductor layer; and
the coaxially arranged second dielectric portion and second semiconductor layer,
the drain contact, in the drain region, being disposed on, and electrically coupled with the first semiconductor layer and the second semiconductor layer.

6. The FinFET of claim 1, wherein the semiconductor layer includes an amorphous-oxide-semiconductor.

7. The FinFET of claim 6, wherein the amorphous-oxide-semiconductor includes at least one of indium-gallium-zinc-oxide, zinc-tantalum-oxide, indium-tin-oxide, zinc-tin-oxide, or indium-zinc-oxide.

8. The FinFET of claim 1, wherein the semiconductor layer includes a direct bandgap semiconductor.

9. The FinFET of claim 1, wherein the semiconductor layer includes a zero bandgap semiconductor.

10. The FinFET of claim 1, wherein the gate dielectric layer includes a dielectric material having a dielectric constant greater than or equal to 3.9.

11. The FinFET of claim 1, further comprising:
a source contact disposed on the source region, the source contact being electrically coupled with the semiconductor layer in the source region; and
a drain contact disposed on the drain region, the drain contact being electrically coupled with the semiconductor layer in the drain region.

12. The FinFET of claim 1, wherein the semiconductor layer is undoped.

13. The FinFET of claim 1, wherein the FinFET is formed on a planar upper surface of a semiconductor device, at least one of the source region or the drain region being electrically coupled with the semiconductor device.

14. A fin field-effect transistor (FinFET), comprising:
a dielectric fin having a proximal end and a distal end;
a semiconductor layer disposed on the dielectric fin, the semiconductor layer longitudinally extending between the proximal end of the dielectric fin and the distal end of the dielectric fin, the semiconductor layer including:
a source region disposed at the proximal end of the dielectric fin;
a drain region disposed at the distal end of the dielectric fin; and
a channel region longitudinally disposed between the source region and the drain region;
a gate dielectric layer disposed on the channel region of the semiconductor layer, the channel region of the semiconductor layer being disposed between the gate dielectric layer and the dielectric portion; and
a conductive gate electrode disposed on the gate dielectric layer, the gate dielectric layer being disposed between the conductive gate electrode and the semiconductor layer.

15. The FinFET of claim 14, wherein:
the dielectric fin includes an oxide fin; and
the semiconductor layer includes an amorphous-oxide-semiconductor.

16. The FinFET of claim 15, wherein the amorphous-oxide-semiconductor includes indium-gallium-zinc-oxide.

17. The FinFET of claim 14, wherein the semiconductor layer includes:
a first portion disposed on a first longitudinal face of the dielectric fin;
a second portion disposed on a second longitudinal face of the dielectric fin, the second longitudinal face being opposite the first longitudinal face;
a third portion disposed on a proximal face of the dielectric fin; and
a fourth portion disposed on a distal face of the dielectric fin,
an upper face of the dielectric fin excluding the semiconductor layer.

18. A fin field-effect transistor (FinFET), comprising:
a fin having a proximal end and a distal end, the fin including:
a source region disposed at the proximal end;
a drain region disposed at the distal end;
a channel region disposed between the source region and the drain region;
a first coaxial structure including:
a first dielectric core;
a first semiconductor layer concentrically disposed on the first dielectric core; and
in the channel region, a first gate dielectric layer concentrically disposed on the first semiconductor layer, the first coaxial structure longitudinally extending between the proximal end and the distal end; and
a second coaxial structure including:
a second dielectric core;
a second semiconductor layer concentrically disposed on the second dielectric core; and
in the channel region, a second gate dielectric layer concentrically disposed on the second semiconductor layer, the second coaxial structure longitudinally extending between the proximal end and the distal end; and
a conductive gate electrode that, in the channel region, surrounds, at least in part, the first coaxial structure and the second coaxial structure.

19. The FinFET of claim 18, wherein the first semiconductor material and the second semiconductor material include an amorphous-oxide-semiconductor.

20. The FinFET of claim 18, wherein:
the first coaxial structure is a first nano-wire structure; and
the second coaxial structure is a second nano-wire structure.

21. The FinFET of claim 18, wherein:
the first coaxial structure is a first nano-sheet structure; and
the second coaxial structure is a second nano-sheet structure.
